(19) United States
(12) Patent Application Publication
(10) Pub. No.: US 2026/0313852 A1
(43) Pub. Date: Oct. 8, 2026

(54) SINGLE-PHASE COOLING SYSTEM CASSETTE

(71) Applicant: AirSys Holding, Inc., Greer, SC (US)

(72) Inventors: Mengyuan Yuan, Anderson, SC (US); Nan Chen, Alpharetta, GA (US); Yunshui Chen, Greer, SC (US)

(21) Appl. No.: 19/391,481

(22) Filed: Nov. 17, 2025

Related U.S. Application Data
(60) Provisional application No. 63/782,795, filed on Apr. 3, 2025.

(51) Int. Cl. H05K 7/20

(52) U.S. Cl. CPC H05K 7/20772

(57) ABSTRACT

A single phase cooling system cassette transfers heat from a primary cooling loop to a secondary cooling loop. The primary cooling loop includes a primary cooling loop portion of a heat exchanger, configured to convert a heated liquid coolant to a cooled liquid coolant by heat transfer to the secondary cooling loop, a sprayer, configured to spray the cooled liquid coolant from the heat exchanger onto one or more heat sinks, a reservoir for the heated liquid coolant, configured to accumulate the heated liquid coolant from the one or more heat sinks, and a pump, configured to suction and pressurize the heated coolant from the reservoir to the primary cooling loop portion of the heat exchanger. The secondary cooling loop may include a secondary cooling loop portion of the heat exchanger. The one or more heat sinks are configured to convert the cooled liquid coolant into the heated liquid coolant.

### PRIORITY

This patent application claims priority from Provisional United States Patent Application number 63/782,795, filed Apr. 3, 2025, entitled DISTRIBUTED SERVER RACK COOLING SYSTEM and naming Nan Chen, Mengyuan Yuan, Zhipeng Zhao, and Yunshui Chen as the inventors, the disclosure of which is incorporated herein in its entirety, by reference.

### FIELD

Illustrative embodiments of the invention generally relate to data center server cooling and, more particularly, various embodiments of the invention relate to a single-phase modular cooling system cassette for efficient data center cooling.

### BACKGROUND

Data centers may include large numbers of computers, data storage, and networking resources. The computers are typically servers, each including one or more very powerful processors and significant memory resources. The servers consume significant amounts of power and produce a large amount of heat, which must be dealt with by the data center.

Data center cooling maintains the right temperatures for servers and associated equipment to prevent overheating and server shutdown and ensure reliable and efficient performance. Formerly, data centers used various forms of air cooling and refrigeration to maintain proper equipment temperatures. However, with dramatic increases in processor and computer operating speeds, traditional air cooling is insufficient. Newer systems use various forms of liquid or oil cooling to maintain equipment temperatures.

### SUMMARY OF VARIOUS EMBODIMENTS

In accordance with one embodiment of the invention, a single phase cooling system cassette transfers heat from a primary cooling loop to a secondary cooling loop. The primary cooling loop includes a primary cooling loop portion of a heat exchanger, configured to convert a heated liquid coolant to a cooled liquid coolant by heat transfer to the secondary cooling loop, a sprayer, configured to spray the cooled liquid coolant from the heat exchanger onto one or more heat sinks, a reservoir for the heated liquid coolant, configured to accumulate the heated liquid coolant from the one or more heat sinks, and a pump, configured to suction and pressurize the heated coolant from the reservoir to the primary cooling loop portion of the heat exchanger. The secondary cooling loop may include a secondary cooling loop portion of the heat exchanger. The one or more heat sinks are configured to convert the cooled liquid coolant into the heated liquid coolant.

In accordance with other embodiments, the reservoir may include an oil drainage/fill port, configured to receive liquid coolant from a source external to the enclosure into the reservoir or suction liquid coolant from the reservoir and a level sensor, configured to detect a liquid coolant level in the reservoir.

In accordance with other embodiments, the cassette may include a rail interface, affixed to a bottom surface of the cassette, configured to allow the cassette to slide in a forward or a reverse direction along a rail.

In accordance with other embodiments, the secondary cooling loop may include quick disconnect fittings of the heat exchanger to facilitate separation of the cassette from the secondary cooling loop.

In accordance with other embodiments, the one or more heat sinks are affixed to one or more components on a server motherboard, where the server motherboard is oriented vertically within the cassette.

In accordance with other embodiments, an enclosure may include the server motherboard, the sprayer, and the reservoir, where the pump and the heat exchanger are outside the enclosure but within the cassette, where the cassette is configured to be modularly removable from a rack.

In accordance with other embodiments, the pump is vibrationally isolated from the enclosure by flexible tubing between the reservoir and a pump inlet of the pump and flexible tubing between a pump outlet of the pump and a heated coolant inlet to the heat exchanger.

In accordance with other embodiments, the reservoir is disposed below the sprayer and the server motherboard and is configured to accumulate the heated liquid coolant by gravity from the one or more heat sinks.

In accordance with other embodiments, the pump is a centrifugal pump located at a same vertical level as the reservoir.

In accordance with other embodiments, the cooled and heated liquid coolant in the primary cooling loop include an oil, where a coolant in the secondary cooling loop includes water.

In accordance with other embodiments, a single phase cooling system cassette may include an enclosure, which includes a server portion, a reservoir portion, and a pump portion. The server portion may include a server motherboard, including one or more heat sinks and a sprayer, configured to spray a cooled liquid coolant onto the one or more heat sinks. The reservoir portion is disposed below the server portion and is configured to accumulate a heated liquid coolant from the one or more heat sinks. The pump portion is affixed to a rear surface of the enclosure and includes a heat exchanger, configured to transfer heat between the heated liquid coolant and a secondary cooling loop and convert the heated liquid coolant into the cooled liquid coolant and a pump, coupled between the reservoir portion and the heat exchanger, configured to suction heated liquid coolant from the reservoir portion and pressurize the heated liquid coolant to the heat exchanger.

In accordance with other embodiments, the sprayer receives the cooled liquid coolant from the heat exchanger.

In accordance with other embodiments, the one or more heat sinks convert the cooled liquid coolant into the heated liquid coolant.

In accordance with other embodiments, the rear surface of the enclosure is configured to face to the rear of a rack when the cassette is installed in the rack.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a front isometric view of a single-phase cooling system cassette in accordance with illustrative embodiments of the invention.

FIG. 2 schematically shows a rear isometric view of a single-phase cooling system cassette in accordance with illustrative embodiments of the invention.

FIG. 3 schematically shows a rear view of a single-phase cooling system cassette in accordance with illustrative embodiments of the invention.

FIG. 4 schematically shows a front isometric view of a single-phase cooling system cassette with external covers removed in accordance with illustrative embodiments of the invention.

FIG. 5 schematically shows a right rear isometric view of a single-phase cooling system cassette with external covers removed in accordance with illustrative embodiments of the invention.

FIG. 6 schematically shows a left rear isometric view of a single-phase cooling system cassette with external covers removed in accordance with illustrative embodiments of the invention.

FIG. 7 schematically shows a block diagram of a single-phase cooling system cassette in accordance with embodiments of the invention.

### DESCRIPTION OF ILLUSTRATIVE EMBODIMENTS

In illustrative embodiments, a single-phase cooling system cassette for use in a data center rack is described. The single-phase cooling system cassette receives a cooled single-phase liquid coolant from a heat exchanger and sprays the liquid coolant through one or more sprayers to heat sinks and other high temperature components of a server motherboard within the cassette.

Data centers generally includes many server computers organized into groups of racks. Each rack may include any number of servers but typically include 10-30 identical computers in a cassette format that may be individually added to or removed from a rack. Each cassette within a rack often includes an associated cooling system to cool very high temperature electronic components, such as central processing units (CPUs) and/or graphical processing units (GPUs). In some cases, other components such as memory modules/devices, northbridge, southbridge, or other components may be individually cooled as well. Each high-temperature component may have an associated heat sink that is cooled by air, a liquid, or a combination of air and a liquid.

Older servers and components produced much less heat than modern components, so air cooling was often sufficient. However, present day individual components may produce over 500 watts of heat, requiring more advanced liquid cooling systems. Illustrative embodiments address this problem with an advanced liquid cooling cassette system for data center applications. Details of various embodiments are discussed below.

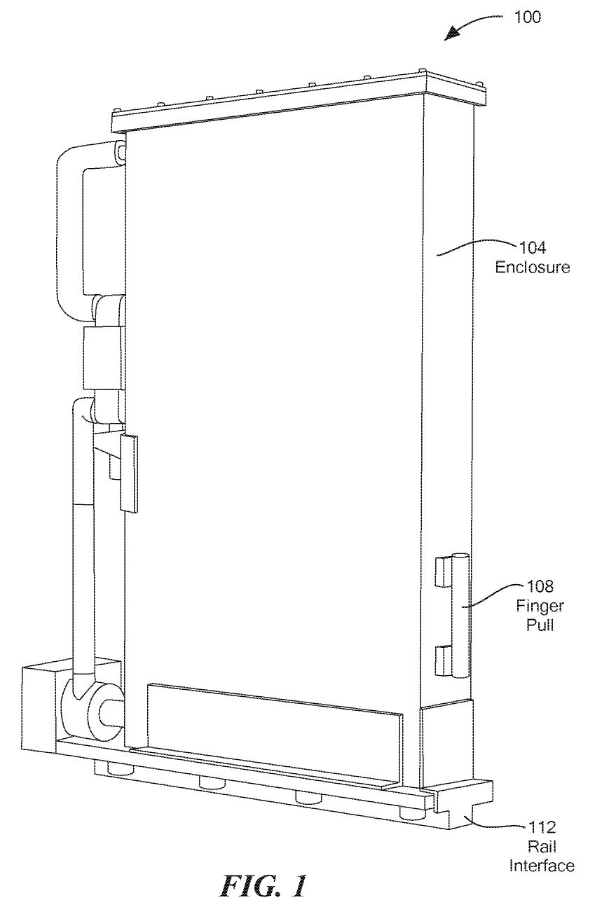

Referring to FIG. 1, a front isometric view of a single-phase cooling system cassette 100 in accordance with illustrative embodiments of the invention is shown. The cooling system cassette 100 includes a sheet metal enclosure 104 and various other components of the cassette-specific cooling system and components to facilitate installation and removal from a rack. The enclosure 104 provides an enclosed space to retain a liquid coolant within to cool various server components. Visible from the front view is a finger pull 108 to provide a grasping server to pull a cassette 100 from a rack to push a cassette 100 into a rack. The bottom of the cassette 100 also includes a rail interface 112. The rail interface 112 includes a rail and rail guides, which guide the cassette 100 as it is being removed from or inserted into a rack. The cassette 100 needs to be modularly removable from a rack to facilitate regular maintenance, component replacement, or perform various forms of hardware upgrades such as a server motherboard, a power supply, a sprayer, a coolant, etc.

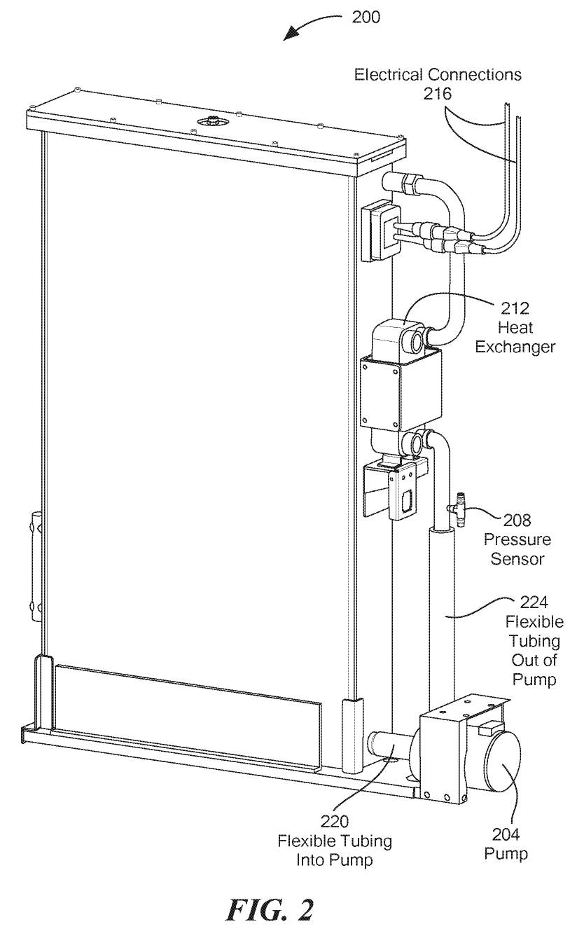

Referring to FIG. 2, a rear isometric view of a single-phase cooling system cassette 200 in accordance with illustrative embodiments of the invention is shown. The rear view 200 illustrates key components related to the cassette cooling system and external interfaces.

The cassette cooling system outside the enclosure 104 includes a pump 204 and a heat exchanger 212. The pump 204 may be a centrifugal pump located at a same height as a coolant reservoir 412 in the enclosure 104. The pump specifications depend on the design of the cassette, the volume of coolant, and coolant throughput needed to adequately cool the primary heat-producing server components. In one embodiment, the coolant may be suctioned from the coolant reservoir 412 and pressurized to about 50 KPa – 180 KPa. The pump 204 pressurizes the coolant to the heat exchanger 212, which is described in more detail herein. To minimize induced vibration from the pump 204 to other components of the cassette 100, the cassette 100 may also include flexible tubing into the pump 220 and flexible tubing out of the pump 224. The flexible tubing 220, 224 may couple to sections of copper or other metal pipes able to carry high temperature liquid coolant. In one embodiment, the pump 204 itself may also have a resilient coupling to sheet metal that holds and supports the pump 204. In one embodiment, the heat exchanger 212 may have one or more pressure sensors 208 affixed to input and output pipes.

The cassette 100 receives power for internal power supplies, the server motherboard, and the pump 204. Preferably, these electrical connections 216 are of a quick disconnect variety that allows fast and reliable power coupling and decoupling to the cassette 100.

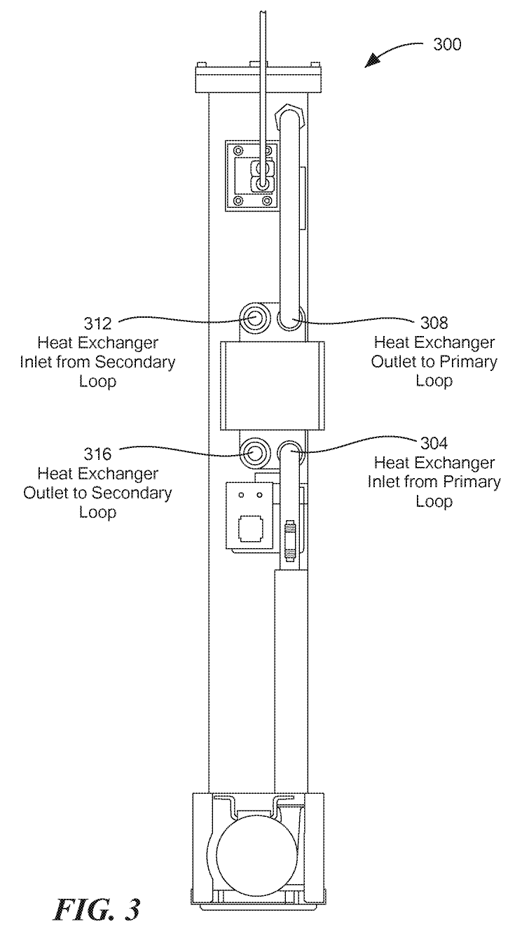

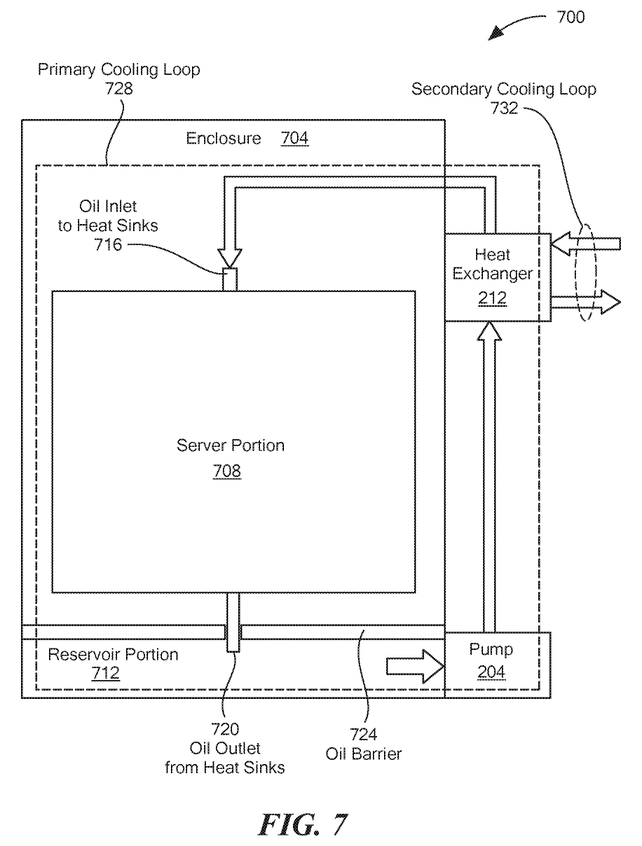

Referring to FIG. 3, a rear view of a single-phase cooling system cassette 300 in accordance with illustrative embodiments of the invention is shown. The rear view 300 illustrates details of connections to the heat exchanger 212 affixed to a rear panel of the enclosure 104. The heat exchanger 212 transfers heat from a primary cooling loop to a secondary cooling loop. The primary cooling loop operates completely within the cassette 100. A portion of the primary cooling loop also passes through the pump 204 and a portion of the heat exchanger 212 (see FIG. 7). Illustrated is a heat exchanger inlet from the primary loop 304 and a heat exchanger outlet to the primary loop 308, with the primary loop portion of the heat exchanger 212 connecting 304 and 308. The inlet from the primary loop 304 receives pressurized heated liquid coolant from the pump 204. The outlet to the primary loop 308 provides cooled liquid coolant to a sprayer in the enclosure 104.

The secondary cooling loop operates completely outside the enclosure 104. A portion of the secondary cooling loop passes through the heat exchanger 212. Illustrated is a heat exchanger inlet from the secondary loop 312 and a heat exchanger outlet to the secondary loop 316, with the secondary loop portion of the heat exchanger 212 connecting 312 and 316. The majority of the secondary cooling loop operates completely outside of the cassette 100, and interfaces to chillers and other cooling apparatuses associated with the data center. Only the primary loop is routed through the enclosure 104.

In one embodiment, the portion of the cassette 100 outside the enclosure 104 may include various pressure and temperature sensors associated with the heated primary loop coolant, the cooled primary loop coolant, and the secondary loop coolant. In one embodiment, cabling from these sensors may be routed to a unified connector mounted to a bracket (see the bracket in FIG. 3 just below the heat exchanger 212).

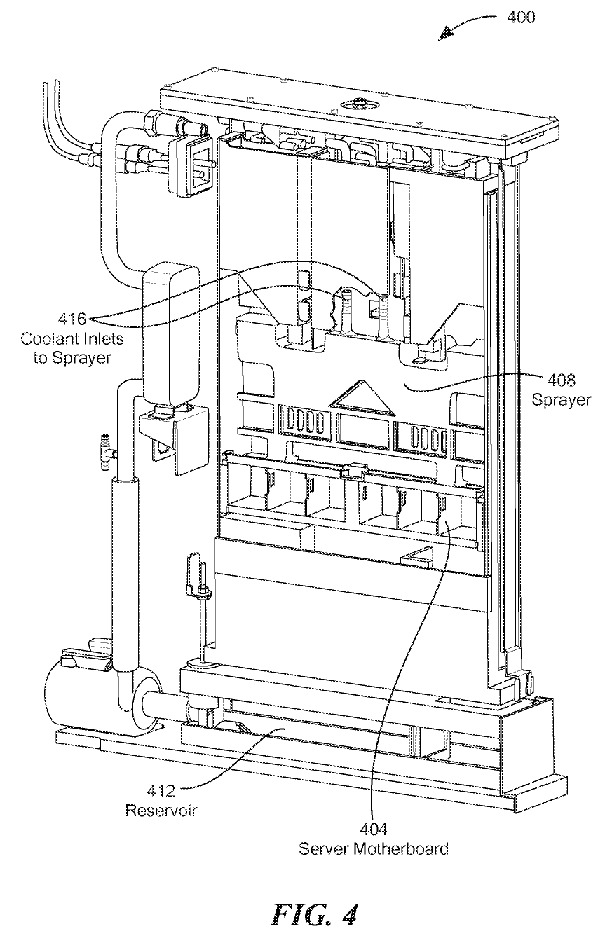

Referring to FIG. 4, a front isometric view of a single-phase cooling system cassette with external covers removed 400 in accordance with illustrative embodiments of the invention is shown. This view illustrates various details within the enclosure 104, including a server motherboard 404, a sprayer 408, and a reservoir 412. The server motherboard includes one or more central processing units (CPUs) and graphics processing units (GPUs), various memory modules, and other core logic components such as northbridge and southbridge devices.

The single phase coolant sprayer 408 sprays cooled liquid coolant onto the heat sinks and other components on the server motherboard 404 that require active liquid cooling. The sprayer 408 may be created by an additive 3D printing process that builds the sprayer 408 in layers. A 3D printer that performs the 3D printing process controls the build from a 3D print file that is constructed beforehand. Various holes, projections, and other features of the sprayer 408 are included in the 3D print file.

In addition to CPU/GPU heat sinks, other heat-producing components such as northbridge/southbridge controllers may require a heat sink. Preferably, the heat sinks are oriented on the heat-producing components such that when the server motherboard 404 is oriented vertically within the enclosure 104, coolant sprayed to the heat sinks will flow off the heat sinks and flow downward by gravity. The sprayer 408 includes a number of spray orifices on one generally planar side that direct a controlled volume of spray to heat sinks on the server motherboard 404. In one embodiment, larger spray orifices are provided for heat sinks requiring a higher volume of liquid coolant and smaller spray orifices are provided for heat sinks or components requiring a lower volume of liquid coolant.

In addition to components with dedicated heat sinks, server motherboards 404 typically include an array of memory modules for data and program storage. The memory modules are generally located in a parallel fashion on the motherboard 404 for efficient layout and near a northbridge controller that controls the memory modules. To provide dedicated cooling for memory modules, the sprayer 408 may include a number of dividers between adjacent memory modules. The dividers keep sprayed liquid coolant between the dividers so that it efficiently cools each memory module and limits overspray to other parts of the server motherboard 404. The dividers are oriented vertically such that the coolant flows between them without pooling against sprayer 408 or server motherboard 404 surfaces.

The sprayer 408 includes a number of coolant inlet ports 416. In the illustrated embodiment, there are two coolant inlet ports 416. A greater number of inlet ports 416 may facilitate more equal and consistent distribution of coolant liquid within a larger sprayer 408, especially when a server motherboard 404 requires a physically large and/or wide sprayer 408. In one embodiment, the coolant inlet ports 416 may include quick-disconnect fittings to facilitate fast installation or removal for servicing. In another embodiment, the coolant inlet ports 416 may include a stepped profile to facilitate use with flexible coolant hoses (e.g., rubber hoses).

Sprayed liquid coolant flows off the heat sinks, memory modules, and other devices of the server motherboard 404 by gravity and enters the coolant reservoir 412 located at a bottom of the enclosure 104. In one embodiment, a series of holes are located in a sheet metal or other baffle between the server motherboard 404 and the reservoir 412 (i.e., oil barrier 724) to facilitate liquid coolant flow. The pump 204 suctions heated primary loop coolant from the reservoir 412. In one embodiment, the liquid coolant operating in the primary cooling loop may include a dielectric oil or other dielectric fluid and the liquid coolant operating in the secondary cooling loop may include water or glycol. Dielectric fluids are electrically non-conductive liquids used in cooling applications where electrical components are present.

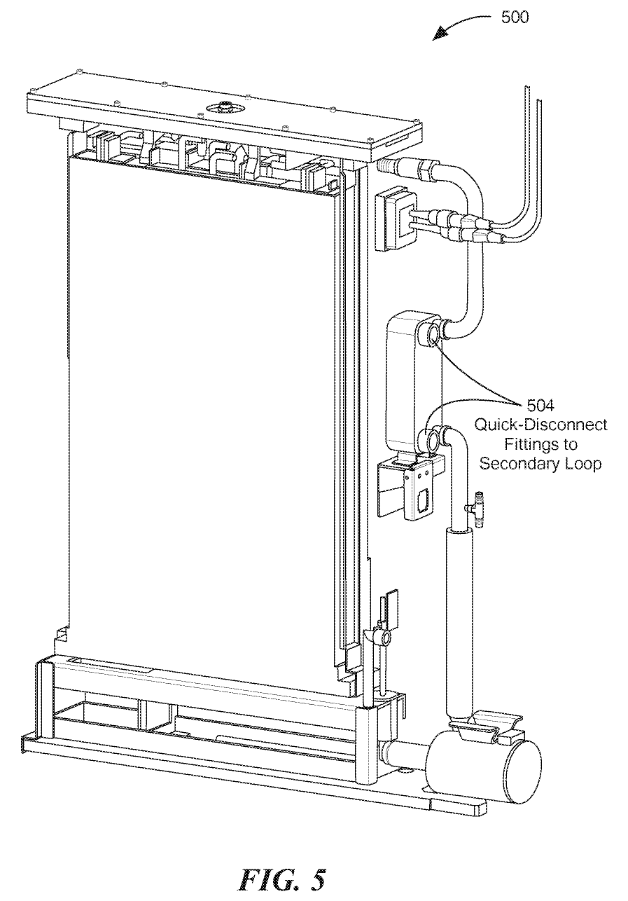

Referring to FIG. 5, a right rear isometric view of a single-phase cooling system cassette with external covers removed 500 in accordance with illustrative embodiments of the invention is shown. The view illustrated in FIG. 5 shows quick-disconnect fittings 504 on the rear of the heat exchanger 212. The quick disconnect fittings 504 allow the coolant connections for the secondary cooling loop to be quickly connected or disconnected. Along with quick-disconnect electrical power connections 216, the quick -disconnect secondary cooling loop connections 504 make rapid installation or removal of a cassette 100 possible.

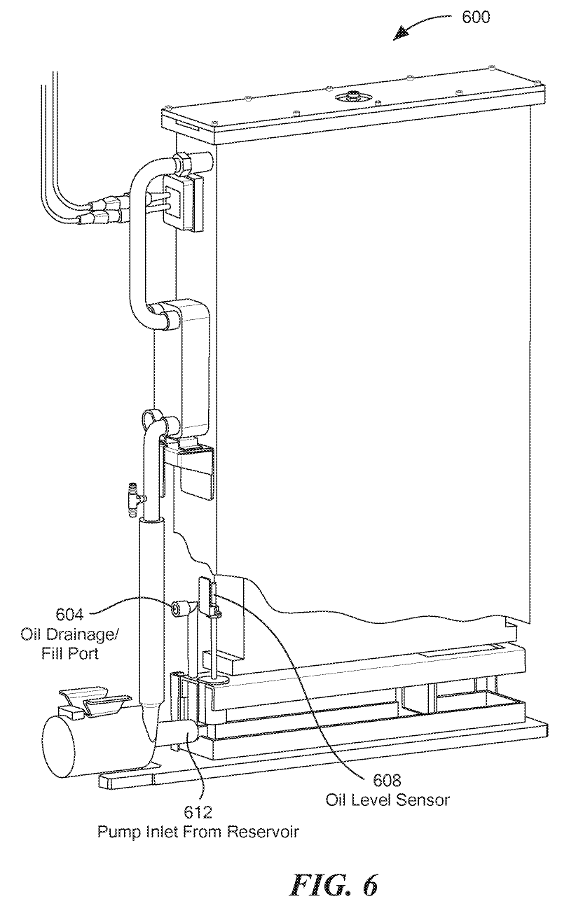

Referring to FIG. 6, a left rear isometric view of a single-phase cooling system cassette with external covers removed 600 in accordance with illustrative embodiments of the invention is shown. FIG. 6 illustrates additional details associated with the reservoir 412. A pump inlet from reservoir 612 is the suction line from the pump 204. An oil drainage/fill port 604 exits the rear of the enclosure 104. This provides an access pathway to the liquid coolant in the reservoir 412 for filling the reservoir 412 and suctioning the liquid coolant from the reservoir 412. An oil level sensor 608 extends upward from the reservoir 412 and provides an indication to a processor of the current oil level in the reservoir 412. For example, a maintenance operation to add more liquid coolant to the reservoir 412 may be initiated if the oil level from the oil level sensor 608 is below a threshold value.

Referring to FIG. 7, a block diagram of a single-phase cooling system cassette 700 in accordance with embodiments of the invention is shown. FIG. 7 illustrates key cassette 100 components in block diagram form.

The enclosure 704, 104 includes two portions, arranged vertically when the cassette 100 is installed to a rack: an upper server portion 708 and a lower reservoir portion 712. The server portion 708 includes the server motherboard 404, the sprayer 408, coupled to the server motherboard 404, cassette power supplies (not shown), the coolant inlets to the sprayer 416, and various coolant and electrical connections within the server portion 708.

The reservoir portion 712 includes the reservoir 412, the oil drainage/fill port 604, he oil level sensor 608, and the pump inlet from the reservoir 612. The server portion 708 is separated from the reservoir portion 712 by an oil barrier 724. The oil barrier 724 has at least one perforation that allows heated liquid coolant from the server portion 708 to flow into the reservoir portion 712 by gravity. The oil barrier 724 may have any number of perforations, although fewer perforations are preferable to limit oil vapor migration from the reservoir portion 712 into the server portion 708.

The server portion 708 includes an oil inlet to heat sinks 716, which is also the coolant inlets to the sprayer 416. Heated liquid coolant in the reservoir portion 712 is suctioned by the pump 204 and pressurized through the heat exchanger 212. Although the pump 204 and the heat exchanger 212 are part of the cassette 100, they are outside the enclosure 704, 104. All of the liquid coolant in the enclosure 704, 104 and the pump 204 is part of the primary cooling loop 728. A primary cooling loop portion of the heat exchanger 212 is also part of the primary cooling loop 728. The remainder of the heat exchanger 212 is the secondary cooling loop portion and part of the secondary cooling loop 732, which extends to chillers and other components that provide heat management for the servers in the data center.

Various embodiments of the invention have been described in fulfillment of the various objectives of the invention. It should be recognized that these embodiments are merely illustrative of the principles of the present invention. Numerous modifications and adaptions thereof will be readily apparent to those skilled in the art without departing from the spirit and scope of the present invention as defined in the following claims.

What is claimed is:

1. A single phase cooling system cassette, configured to transfer heat from a primary cooling loop to a secondary cooling loop, the primary cooling loop comprising:
a primary cooling loop portion of a heat exchanger, configured to convert a heated liquid coolant to a cooled liquid coolant by heat transfer to the secondary cooling loop, the secondary cooling loop comprising a secondary cooling loop portion of the heat exchanger;
a sprayer, configured to spray the cooled liquid coolant from the heat exchanger onto one or more heat sinks, the one or more heat sinks configured to convert the cooled liquid coolant into the heated liquid coolant;
a reservoir for the heated liquid coolant, configured to accumulate the heated liquid coolant from the one or more heat sinks; and
a pump, configured to suction and pressurize the heated coolant from the reservoir to the primary cooling loop portion of the heat exchanger.

2. The single phase cooling system cassette of claim 1, wherein the reservoir comprises:
an oil drainage/fill port, configured to receive liquid coolant from a source external to the enclosure into the reservoir or suction liquid coolant from the reservoir; and
a level sensor, configured to detect a liquid coolant level in the reservoir.

3. The single phase cooling system cassette of claim 1, wherein the cassette comprises:
a rail interface, affixed to a bottom surface of the cassette, configured to allow the cassette to slide in a forward or a reverse direction along a rail.

4. The single phase cooling system cassette of claim 1, wherein the secondary cooling loop comprises quick disconnect fittings of the heat exchanger to separate the cassette from the secondary cooling loop.

5. The single phase cooling system cassette of claim 1, wherein the one or more heat sinks are affixed to one or more components on a server motherboard, wherein the server motherboard is oriented vertically within the cassette.

6. The single phase cooling system cassette of claim 5, wherein an enclosure comprises the server motherboard, the sprayer, and the reservoir, wherein the pump and the heat exchanger are outside the enclosure but within the cassette, wherein the cassette is configured to be modularly removable from a rack.

7. The single phase cooling system cassette of claim 6, wherein the pump is vibrationally isolated from the enclosure by flexible tubing between the reservoir and a pump inlet of the pump and flexible tubing between a pump outlet of the pump and a heated coolant inlet to the heat exchanger.

8. The single phase cooling system cassette of claim 5, wherein the reservoir is disposed below the sprayer and the server motherboard and is configured to accumulate the heated liquid coolant by gravity from the one or more heat sinks.

9. The single phase cooling system cassette of claim 1, wherein the pump is a centrifugal pump located at a same vertical level as the reservoir.

10. The single phase cooling system cassette of claim 1, wherein the cooled and heated liquid coolant in the primary cooling loop comprises a dielectric fluid, wherein a coolant in the secondary cooling loop comprises one or more of water and glycol.

11. A single phase cooling system cassette, comprising:
an enclosure, comprising:
a server portion, comprising:
a server motherboard, comprising one or more heat sinks; and
a sprayer, configured to spray a cooled liquid coolant onto the one or more heat sinks;
a reservoir portion, disposed below the server portion, configured to accumulate a heated liquid coolant from the one or more heat sinks; and
a pump portion, affixed to a rear surface of the enclosure, comprising:
a heat exchanger, configured to transfer heat between the heated liquid coolant and a secondary cooling loop and convert the heated liquid coolant into the cooled liquid coolant; and
a pump, coupled between the reservoir portion and the heat exchanger, configured to suction heated liquid coolant from the reservoir portion and pressurize the heated liquid coolant to the heat exchanger.

12. The single phase cooling system cassette of claim 11, wherein the reservoir portion comprises:
an oil drainage/fill port, configured to receive liquid coolant from a source external to the enclosure into the reservoir portion or suction liquid coolant from the reservoir portion; and
a level sensor, configured to detect a level of liquid coolant in the reservoir portion.

13. The single phase cooling system cassette of claim 11, wherein the enclosure comprises:
a rail interface, affixed to a bottom surface of the cassette, configured to allow the cassette to slide in a forward or rearward direction along a rail.

14. The single phase cooling system cassette of claim 11, wherein the secondary cooling loop comprises quick disconnect fittings of the heat exchanger to separate the cassette from the secondary cooling loop.

15. The single phase cooling system cassette of claim 11, wherein the pump is vibrationally isolated from the enclosure by flexible tubing between the reservoir portion and a pump inlet and flexible tubing between a pump outlet and a heated coolant inlet to the heat exchanger.

16. The single phase cooling system cassette of claim 11, wherein the pump is a centrifugal pump located at a same vertical level as the reservoir portion.

17. The single phase cooling system cassette of claim 11, wherein the cooled and heated liquid coolant in the primary cooling loop comprises a dielectric fluid, wherein a coolant in the secondary cooling loop comprises one or more of water and glycol.

18. The single phase cooling system cassette of claim 11, wherein the sprayer receives the cooled liquid coolant from the heat exchanger.

19. The single phase cooling system cassette of claim 11, wherein the one or more heat sinks convert the cooled liquid coolant into the heated liquid coolant.

20. The single phase cooling system cassette of claim 11, wherein the rear surface of the enclosure is configured to face to the rear of a rack when the cassette is installed in the rack.
